(19) United States
(12) Patent Application Publication
(10) Pub. No.: US 2013/0308272 A1
(43) Pub. Date: Nov. 21, 2013

(54) HEAT PIPE AND ELECTRONIC COMPONENT HAVING THE HEAT PIPE

(71) Applicant: Norifumi Furuta, Toyota-shi (JP)

(72) Inventor: Norifumi Furuta, Toyota-shi (JP)

(21) Appl. No.: 13/982,543

(22) PCT Filed: Feb. 1, 2012
(86) PCT No.: PCT/IB12/00166

§ 371 Date: Jul. 30, 2013

(30) Foreign Application Priority Data
Feb. 3, 2011 (JP) 2011-022054

(51) Int. Cl. F28D 15/04; H05K 7/20

(52) U.S. Cl. CPC F28D 15/04; H05K 7/20336
USPC 361/700; 165/104.26

(57) ABSTRACT

A heat pipe includes a laminate formed by laminating a plurality of flat plates and having capillary tubes formed in the interior thereof, and a working fluid contained in the capillary tubes and operable to transfer heat. In the heat pipe, the laminate has insulating layers made of an insulating material and metal layers made of a metal material, which are alternately laminated.

### BACKGROUND OF THE INVENTION

1. Field of the Invention

The invention relates to a heat pipe including a laminate of flat plates, and a working fluid contained in the laminate, and also relates to an electronic component including the heat pipe.

2. Description of Related Art

Heat pipes are widely known as cooling devices. As is well known in the art, the heat pipe has capillary tubes that provide enclosed spaces, and water or an alternative for chlorofluorocarbon that functions as a working fluid is fluid-tightly contained in the capillary tubes. When heat is generated at one end of the heat pipe, the working fluid contained therein vaporizes, so that the heat is introduced into the heat pipe as latent heat (heat of vaporization). Then, the vaporized working fluid moves to a low-temperature portion at the other end of the heat pipe, where the working fluid is cooled, returns to a liquid state, and releases the heat. The liquefied working fluid moves to the vicinity of a heat generator (or a source of heat), due to the effect of capillarity, and receives heat from the heat generator again, to be vaporized. Then, the working fluid repeats the cycle of vaporization and liquefaction in the same manner, so as to continuously transfer heat with high efficiency, and cool the heat generator.

Some examples of the heat pipe are integrally incorporated into other electronic components. For example, Japanese Patent Application Publication No. 2006-41024 (JP-A-2006-41024) discloses a printed wiring board within which capillary tubes made of metal and containing working fluid are placed. The capillary tubes described in JP-A-2006-41024 function as so-called heat pipes. With the heat pipes thus formed within the printed wiring board, as described in JP-A-2006-41024, heat can be efficiently released from an electronic component installed on the printed wiring board, to the outside.

However, the technology of JP-A-2006-41024 was developed for the purpose of improving the cooling efficiency in connection with the printed wiring board, and it was difficult to apply the same technology to other types of electronic components. In particular, it was difficult to apply the above technology to cooling of electronic components, such as a reactor, a transformer, and a stator of a motor/generator, which are required to have inductance.

Japanese Patent Application Publications No. 2007-129817 and No. 2009-212384 disclose technologies for cooling electronic components that are required to have inductance. More specifically, JP-A-2007-129817 discloses a technology cooling a reactor core, using radiating fins provided on an outer circumferential surface of the reactor core. Also, JP-A-2009-212384 discloses a technology of cooling a reactor core, using a heat pipe provided at the middle of the reactor core having a generally annular shape as seen in its top plan view. However, the cooling devices described in JP-A-2007-129817 and JP-A-2007-129817 are both arranged to cool the reactor core from its outer surface, and thus suffer from a poor cooling efficiency

### SUMMARY OF THE INVENTION

The invention provide a heat pipe that can more efficiently cool an electronic component that is required to have inductance, and an electronic component including the heat pipe.

A first aspect of the invention provides a heat pipe including a laminate formed by laminating a plurality of flat plates and having capillary tubes formed in the interior thereof, and a working fluid contained in the capillary tubes and operable to transfer heat. In the heat pipe, the laminate includes insulating layers made of an insulating material and metal layers made of a metal material, which are alternately laminated.

In the heat pipe according to the first aspect of the invention, at least one of the flat plates of the laminate may be formed with grooves or holes that provide the capillary tubes, and the flat plates of the laminate may include Metal flat plates each of which has a surface on which an insulating film that provides the insulating layer is formed.

A second aspect of the invention provides an electronic component including the heat pipe as described above, and a coil wound around an outer periphery of the heat pipe.

In this case, the electronic component may further include a core material on which the coil is wound, and the heat pipe may include a heat generating portion that is inserted in the core material and is arranged to receive heat, and a heat dissipating portion that protrudes outward from the core material and is arranged to release the received heat to the outside. Also, a cooling member that releases heat to the outside may be mounted on an outer surface of the heat dissipating portion of the heat pipe. Also, the coil may be a reactor coil, and the core material may be a reactor core.

According to the invention, the metal layers and the insulating layers are alternately laminated, and the laminate of the metal layers and insulating layers performs substantially the same functions as a laminate of electromagnetic steel sheets. Thus, when the heat pipe is used for cooling the core material, the inductance can be kept at a high level.

### BRIEF DESCRIPTION OF THE DRAWINGS

Features, advantages, and technical and industrial significance of an exemplary embodiment of the invention will be described below with reference to the accompanying drawings, in which like numerals denote like elements, and wherein:

FIG. 1 is a schematic perspective view of a reactor as one embodiment of the invention;

FIG. 2 is a schematic perspective view of a heat pipe used in the reactor of the embodiment of FIG. 1;

FIG. 3 is a schematic cross-sectional view taken along line AA in FIG. 2; and

FIG. 4 is a schematic perspective view of another example of heat pipe.

### DETAILED DESCRIPTION OF EMBODIMENTS

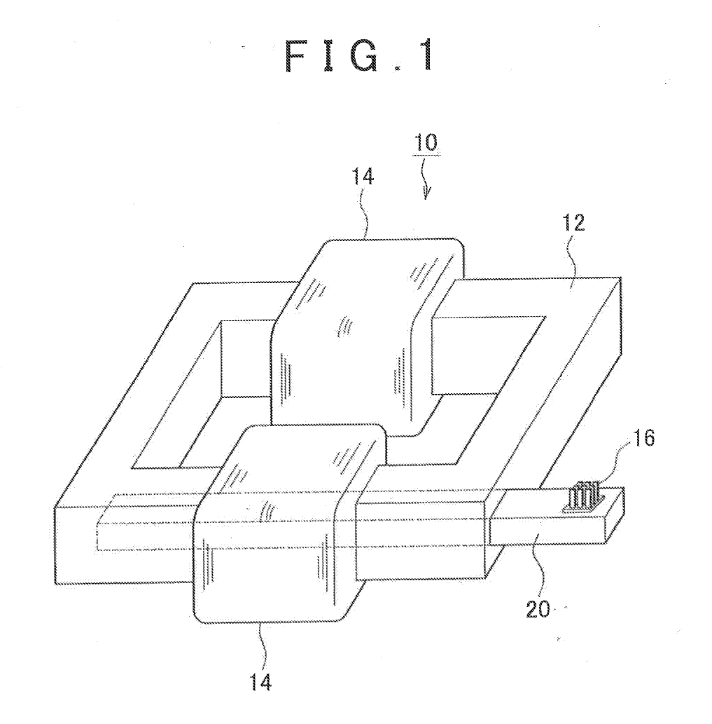

One embodiment of the invention will be described with reference to the drawings. FIG. 1 is a schematic perspective view of a reactor 10 as one embodiment of the invention.

As is well known in the art, the reactor 10 is an electronic component that serves as a passive element using coil windings, and is required to have inductance. The reactor 10 is installed in, for example, a step-up converter, for conversion of electromagnetic energy. The reactor 10 of this embodiment includes a reactor core 12 shaped like a frame as seen in a top plan view, reactor coils 14 wound on the reactor core 12, and a heat pipe 20 a part of which is inserted in the reactor core 12.

The reactor core 12 has two opposed portions in the form of rectangular parallelepipeds, and connecting portions that connect corresponding end portions of the rectangular parallelepipeds to each other, and a part or the whole of each of the rectangular parallelepipeds provides a coil winding portion on which the reactor coil 14 is wound. The reactor core 12 is formed by joining a plurality of magnetic members via gap portions (not shown). For example, a green compact of soft magnetic powder, or a laminate of electromagnetic steel sheets, is used as each of the magnetic members. The gap portions, which are interposed between the magnetic members, are used for controlling the inductance of the reactor core 12, and are formed of a non-magnetic material, such as alumina.

Each of the reactor coils 14 consists of a winding wire wound on a corresponding one of the coil winding portions of the frame-like reactor core 12. The winding wire consists of a conductor, and an insulating film that covers the periphery of the conductor. The conductor may be formed of a metal material having high electric conductivity, and the insulating film may be formed of, for example, enamel. The cross-sectional shape of the winding wire may be selected from various forms, such as a circle, ellipse, and polygons.

Generally, in the reactor 10, the reactor core 12 generates heat in accordance with electromagnetic energy conversion. The resulting increase in the temperature due to the heat generated in the reactor core 12 brings about problems, such as reduction of the voltage conversion efficiency in the step-up converter using the reactor 10.

In order to solve the above problem, it was proposed in the related art to form radiating or heat-dissipating fins integrally on a surface of the reactor core, or place a heat pipe between the two coil winding portions. However, these technologies merely allow heat to be dissipated from the outer surface of the reactor core, and the temperature is likely to build up in the interior of the reactor core.

In order to solve the above problem, the reactor 10 of this embodiment is constructed such that a part of the heat pipe 20 is inserted in the reactor core 12, so as to cool the reactor core 12 from the inside thereof.

However, if a known heat pipe that is in wide use, for example, a heat pipe having a circular tube or tubes containing a working fluid, is inserted in the reactor core 12, the inductance value of a portion of the reactor core 12 in which the heat pipe is inserted is undesirably reduced. To compensate for the reduction of the inductance, the size of the reactor core 12 needs to be increased. In this embodiment, the heat pipe 20 inserted into the reactor core 12 is specially constructed so as to solve the above problem. In the following, the heat pipe 20 will be described in detail.

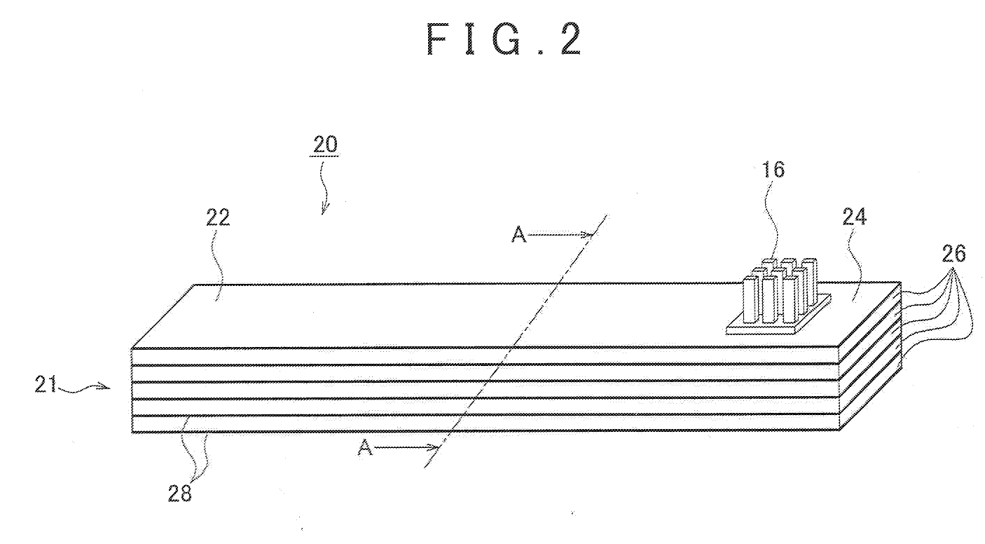

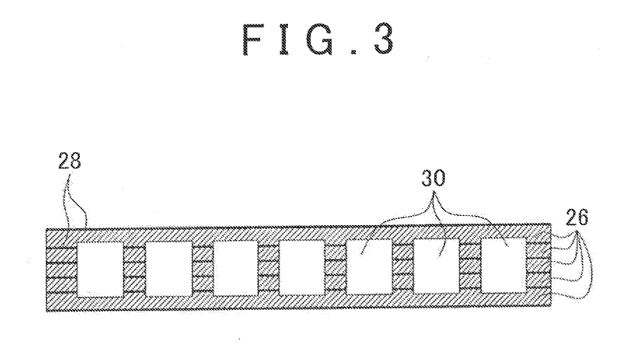

FIG. 2 is a schematic perspective view of the heat pipe 20 used in this embodiment. FIG. 3 is a schematic cross-sectional view taken along line A-A in FIG. 2.

The heat pipe 20 of this embodiment includes a laminate 21 formed by laminating or stacking a plurality of metal flat plates 26, and a working fluid (not shown) fluid-tightly contained in capillary tubes 30 formed in the interior of the laminate 21. As shown in FIG. 2 and FIG. 3, the laminate 21 is in the form of a rectangular parallelepiped having a large length in one direction, and a portion of the laminate 21 is inserted in the reactor core 12, while the remaining portion protrudes outward from the reactor core 12. The portion of the laminate 21 inserted in the reactor core 12 functions as a heat generating portion 22 that receives heat from the reactor core 12 as a heat generator. Also, the portion of the laminate 21 protruding outward from the reactor core 12 functions as a heat dissipating portion 24 that dissipates the heat transferred from the heat generating portion 22, to the outside. A heat dissipating member 16, such as a heat sink or cooling fins, which efficiently dissipates heat to the outside, is mounted on the heat dissipating portion 24.

A plurality of capillary tubes 30 that extend in the longitudinal direction (in which the heat generating portion 22 and the heat dissipating portion 24 are connected) are formed in the interior of the laminate 21. The working fluid is fluid-tightly contained in the capillary tubes 30. The working fluid is a liquid that transfers heat generated in the heat generating portion 22 to the heat dissipating portion 24, and water, an alternative for chlorofluorocarbon, or the like, may be used as the working fluid. In operation, the working fluid repeats a cycle of evaporation (vaporization) and condensation (liquefaction), so that the heat generated in the heat generating portion 22 is effectively dissipated or released to the outside.

Namely, the working fluid absorbs heat generated in the heat generating portion 22 of the laminate 21 as latent heat, and evaporates (vaporizes). The vaporized working fluid moves to the heat dissipating portion 24 or its vicinity having a relatively low temperature, releases the latent heat, and condenses (liquefies). The liquefied working fluid moves to the heat generating portion 22 or its Vicinity, due to the effect of capillarity, gravity, or self-excited vibrations caused by boiling of the working fluid, for example, and vaporizes again. Then, the working fluid repeats the cycle of evaporation and condensation, so as to release the heat received from the heat generating portion 22 to the outside via the heat dissipating portion 24, so that the heat generated in the heat generating portion 22 can be effectively dissipated or released.

The laminate 21 is a stack of metal flat plates 26, as described above. Holes and/or grooves are formed in advance in at least a part of the metal flat plates 26 that constitute the laminate 21, so that the capillary tubes 30 are formed in the laminate 21 when the metal flat plates 26 having the holes and/or grooves are laminated or stacked together.

Each of the metal flat plates 26 is a thin plate or sheet made of metal, and an insulating film 28, such as a polyimide film or a ceramic film, is formed on a surface of the metal flat plate 26. While the thickness of each metal flat plate 26 illustrated in FIG. 2 and FIG. 3 is relatively large as compared with the size of the laminate 21, for easy viewing, the laminate 21 is actually formed by stacking a larger number of metal flat plates 26 each having a smaller thickness than that of the illustrated ones.

The laminate 21 of this embodiment is formed by stacking the metal flat plates 26 on which the insulating films 28 are formed, such that insulating layers formed by the insulating films 28 and metal layers formed by the metal flat plates 26 are alternately laminated, like the above-mentioned laminate of electromagnetic steel sheets. When the laminate 21 thus constructed is inserted in the reactor core 12, the occurrence of eddy current can be effectively prevented, and the inductance can be kept at a high level, as is the case with the laminate of electromagnetic steel sheets. While metal flat plates made of copper having high thermal conductivity are used as the metal flat plates 26 in this embodiment, the metal flat plates 26 may also be formed of a ferromagnetic material, such as iron, in place of copper, in order to provide even higher inductance. In any event, the insulating film 28 is formed on the surface of each of the metal flat plates 26, and the metal flat plates 26 are laminated or stacked together, so that the inductance can be kept at a high level, like the laminate of electromagnetic steel sheets.

While the insulating layers are formed by the insulating films 28 formed on the metal flat plates 26 in this embodiment, the insulating layers may be formed by insulating plates that are thin plates made of an insulating material. Namely, metal flat plates on which no insulating films are formed, and insulating plates may be alternately superposed on each other, so as to form a laminated structure in which insulating layers (the insulating plates) and metal layers (the metal flat plates) are alternately laminated.

Next, the operation of the reactor 10 thus constructed will be described. When current passes through the reactor coils 14 as the step-up converter, or the like, in which the reactor 10 is installed is driven, heat is generated in the reactor coils 14 and the reactor core 12. A part of the heat generated in the reactor 10 is transmitted from the outer surfaces of the reactor coils 14 and the reactor core 12 to the outside space, and is dissipated. However, the dissipation of heat from the outer surfaces may be deemed unsatisfactory, and a large amount of heat may remain in the reactor core 12 if the heat is dissipated only from the outer surfaces. This results in a rise of the temperature of the reactor core 12, which brings about problems, such as reduction of the voltage conversion efficiency of the step-up converter. In particular, the heat within the reactor core is less likely or unlikely to be dissipated from its outer surface, and is likely to remain in the interior of the reactor.

In this embodiment, however, the heat pipe 20 is inserted in the reactor core 12, as described above. Accordingly, heat remaining in the reactor core 12 is efficiently transmitted to the heat pipe 20. Namely, heat generated in the reactor core 12 is transmitted to the working fluid contained in the capillary tubes 30, via the heat generating portion 22 (a portion of the laminate 21 which is in contact with the reactor core 12) of the heat pipe 20. The working fluid absorbs the transferred heat as latent heat, and vaporizes. The vaporized working fluid moves to a location right under the low-temperature heat dissipating portion 24 (a portion of the laminate 21 which protrudes from the reactor core 12), and exchanges heat with the heat dissipating portion 24. Through the heat exchange, the working fluid dissipates or releases the latent heat, and liquefies. The heat dissipating portion 24 that receives the heat from the working fluid dissipates or releases the heat to the outside, via the heat dissipating member 16 (such as cooling fins or heat sink) provided for heat dissipation. The liquefied working fluid moves again to a location right under the heat generating portion 22, due to the effect of the gravity, capillarity, or self-excited vibrations, for example. Then, the working fluid repeats the cycle of vaporization and liquefaction in the same manner, so as to efficiently release the heat of the reactor core 12 to the outside.

In many examples of the related art, the reactor core is cooled only from the outside, but hardly cooled from the inside thereof. In this embodiment, however, the heat generating portion 22 of the heat pipe 20 is inserted into the reactor core 12, and the reactor core 12 is cooled from the inside thereof, as is apparent from the above description. As a result, the reactor core 12 can be efficiently cooled. Consequently, the temperature of the reactor core 12 can be prevented from rising excessively, and the efficiency of various electronic components (such as a step-up converter) in which the reactor 10 is installed can be prevented from deteriorating.

However, the use of known heat pipes in the form of circular tubes made of copper, which are in wide use, may cause a problem that the inductance of the reactor is reduced. Namely, the cross-sectional area of the reactor core is reduced by an amount corresponding to the volume of the heat pipes inserted in the reactor core, resulting in reduction of the inductance.

In this embodiment, on the other hand, the heat pipe 20 in the form of the laminate 21 of the metal layers and insulating layers that are alternately laminated on each other, like the above-indicated laminate of electromagnetic steel sheets, is used. in this case, the laminate 21 that provides the heat pipe 20 functions, by itself, as a part of the reactor core 12; therefore, otherwise possible reduction of the inductance is prevented. Thus, according to this embodiment, it is possible to effectively cool the reactor core 12, while keeping the inductance at a high level, without increasing the size of the reactor core 12.

While the heat pipe 20 is inserted only in a portion of the reactor core 12 right under one of the reactor coils 14 in the embodiment of FIG. 1, another heat pipe 20 may also be inserted in a portion of the reactor core 12 right under the other reactor coil 14. Namely, two heat pipes 20 may be inserted in one reactor core 12 at two different locations.

While the heat pipe 20 is inserted in the reactor core 12 in this embodiment, the heat pipe 20 itself may be used as the reactor core 12. Namely, the reactor coil 14 may be directly wound on the laminate-type heat pipe 20 used in this embodiment.

While the heat pipe 20 is used with the reactor 10 in this embodiment, the technology of this invention may also be applied to other electronic components, such as a transformer and a stator of a motor, which are required to have inductance. Namely, a part of the laminate-type heat pipe 20 used in this embodiment maybe inserted in a core of a transformer or a stator core of a motor, or the heat pipe 20 itself may be used as the core.

While the heat pipe 20 in the form of a rectangular parallelepiped has been illustrated in the above description, the shape of the heat pipe 20 may be changed as needed provided that the heat pipe 20 has a stacked or laminated structure in which the metal layers and the insulating layers are alternately laminated or stacked together. Also, the capillary tubes 30 formed in the heat pipe 20 are not necessarily straight tubes, but may be bent, or serpentine tubes.

As is apparent from the above description, the top layer of the heat pipe 20 of this embodiment is provided by an insulating layer. The heat pipe 20 whose top face is provided by the insulating layer is useful not only for cooling the core, but also useful for cooling an electronic component, such as a semiconductor device.

Namely, when an electronic component, such as a semiconductor device, is cooled by the heat pipe 20, the electronic component is normally mounted on the heat generating portion 22 of the heat pipe 20. In many known examples, the upper surface of the heat pipe is formed of metal, and therefore, an insulator needs to be additionally provided between the heat generator (semiconductor device) and the heat generating portion of the heat pipe. The installation of the insulator is not only cumbersome, but also results in increase of the thermal resistance (between the heat generator and the working fluid), and deterioration of the cooling efficiency.

On the other hand, when the top layer on which the semiconductor device is mounted is provided by an insulating layer, there is no need to additionally provide an insulator between the heat generator and the heat generating portion 22. As a result, the time and effort required to mount the semiconductor device on the heat pipe can be reduced. Also, the absence of the additional insulator leads to reduction of the distance between the heat generator and the heat generating portion 22 by an amount corresponding to the thickness of the insulator, and reduction of the thermal resistance between the heat generator and the working fluid. Consequently, the semiconductor device can be efficiently cooled.

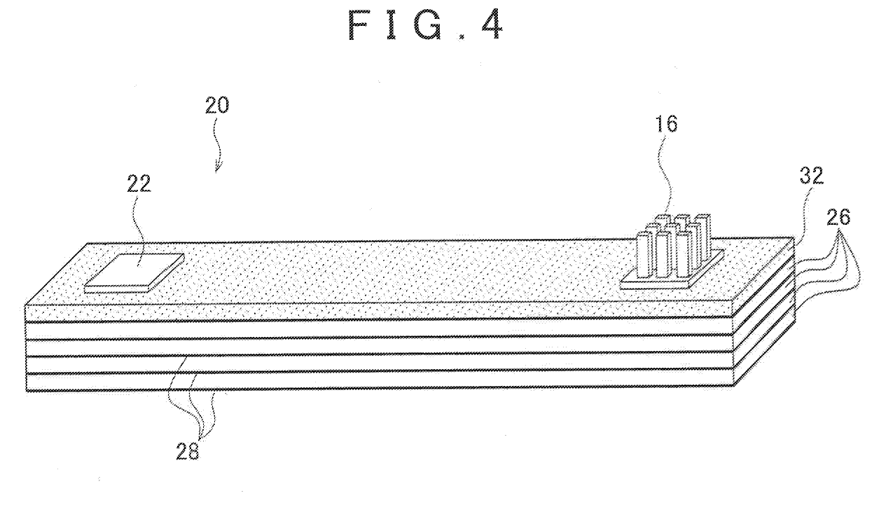

In the case where a semiconductor device is cooled, it is desirable to use a flat plate (insulating plate) made of an insulating material, for forming an insulating layer as the top layer of the heat pipe, in place of the insulating film 28 formed on the surface of the metal flat plate 26. Namely, as shown in FIG. 4, an insulating plate 32 made of an insulating material, such as silicon, is mounted on the upper surface of the heat pipe 20. The use of the insulating plate 32 makes it possible to insulate the semiconductor device with improved reliability.

1. A heat pipe comprising:
a laminate formed by laminating a plurality of flat plates and having capillary tubes formed in the interior thereof; and
a working fluid contained in the capillary tubes and operable to transfer heat,
wherein
the laminate comprises insulating layers made of an insulating material and metal layers made of a metal material, which are alternately laminated.

2. The heat pipe according to claim 1, wherein:
at least one of the flat plates of the laminate is formed with grooves or holes that provide the capillary tubes; and
the flat plates of the laminate comprise metal flat plates each of which has a surface on which an insulating film that provides the insulating layer is formed.

3. The heat pipe according to claim 1, wherein:
the metal material is a ferromagnetic metal material.

4. An electronic component comprising:
a heat pipe in accordance with claim 1; and
a coil wound around an outer periphery of the heat pipe.

5. The electronic component according to claim 4, wherein:
at least one of the flat plates of the laminate is formed with grooves or holes that provide the capillary tubes; and
the flat plates of the laminate comprise metal flat plates each of which has a surface on which an insulating film is formed.

6. The electronic component according to claim 4, further comprising a core material on which the coil is wound, wherein
the heat pipe includes a heat generating portion that is inserted in the core material and is arranged to receive heat, and a heat dissipating portion that protrudes outward from the core material and is arranged to release the received heat to the outside.

7. The electronic component according to claim 6, wherein a cooling member that releases heat to the outside is mounted on an outer surface of the heat dissipating portion of the heat pipe.

8. The electronic component according to claim 4, wherein the coil is a reactor coil, and the core material is a reactor core.
